(19) United States
(12) Patent Application Publication
(10) Pub. No.: US 2015/0331271 A1
(43) Pub. Date: Nov. 19, 2015

(54) POST SPACER AND DISPLAY SUBSTRATE

(71) Applicant: BOE TECHNOLOGY GROUP CO., LTD., Beijing (CN)

(72) Inventors: CHENGTAN ZHAO, Beijing (CN); JAEGEON YOU, Beijing (CN)

(21) Appl. No.: 14/528,296

(22) Filed: Oct. 30, 2014

(30) Foreign Application Priority Data
May 15, 2014 (CN) 201410204687.0

(51) Int. Cl. G02F 1/1339; G03F 7/20; G02F 1/1337

(52) U.S. Cl. CPC G02F 1/13394; G02F 1/1337; G03F 7/20

(57) ABSTRACT

Disclosed is a post spacer and display substrate, a cross section of the post spacer in the direction perpendicular to the height direction comprising a first portion that is symmetrical with respect to an axis in a first direction, the maximal width of the first portion in a second direction perpendicular to the first direction being the maximal width of the whole cross section in the second direction, and the width of the first portion decreasing progressively along the first direction, wherein a shape between a vertex of the first portion in the first direction and each of the two endpoints defining said maximal width is a straight line, and an included angle between both straight lines is less than or equal to 90 degree, or a shape between a vertex of the first portion in the first direction and each of the two endpoints defining said maximal width is a convex arc, an included angle between both straight lines connecting respectively the vertex to each of the two endpoints is less than or equal to 90 degree, and the convex arc is different from the circular arc on a circle with the straight line segment connecting the two endpoints being the diameter thereof.

### FIELD OF THE INVENTION

The present disclosure relates to the field of liquid crystal display technologies, and particularly to a post spacer and display substrate.

### BACKGROUND OF THE DISCLOSURE

In the field of liquid crystal display technologies, post spacers are generally arranged on the region corresponding to black matrices of a display substrate (e.g. a color filter substrate or an array substrate) for supporting the color filter substrate and the array substrate. As a continuous increase in the resolution of the display, the number of pixels on a unit area becomes larger and larger. To guarantee a higher aperture ratio (or a larger light-emitting region) for each pixel, the black matrices are manufactured smaller and smaller in size. This requires that each pixel, in addition to the black matrices, is have a highly precise display region structure (e.g. an alignment layer).

The alignment of the alignment layer is achieved by rubbing on an organic resin layer to be rubbed using a rubbing cloth with rubbing piles. Ideally, when the surface of the organic resin layer is flat and the rubbing piles on the rubbing cloth distribute uniformly and are of the same specification (i.e. the length and diameter), the rubbing strength may be uniform on the organic resin layer, resulting in a consistent depth and direction of rubbing marks.

However, prior to forming the alignment layer, the post spacers are generally needed to be formed on the substrate. Therefore, in forming the alignment layer, the organic resin layer is, in practice, arranged on the substrate with the post spacers having been formed thereon. In other words, the organic resin layer is not flat. In this case, when the rubbing piles sweep over the protrusions corresponding to the post spacers, rubbing marks would be produced at the locations adjacent to each post spacer in the pixel display region, where the depth of the rubbing marks is shallower than that elsewhere, or even no rubbing mark would be produced at these locations. This may render the liquid crystal molecules corresponding to these locations unaligned by the alignment layer and thus lead to a light-leaking effect.

FIG. 1 is a top view of a post spacer 100 in the prior art. As is shown in the figure, the post spacer 100 is post-like, and the rubbing piles on the rubbing cloth rub the organic resin layer on the substrate body 10 in the rubbing direction, sweeping over a first contact side, and in turn a second one of the post spacer 100. Due to a regular circular shape of the cross section of the post spacer 100 and the blockage of the post spacer itself as a protrusion, the rubbing piles may be caused to “skip” to such a degree that they pass over the second contact side and the organic resin layer in the neighboring region thereof. Thus, the organic resin layer in this region would not be rubbed or only rubbed with shallow rubbing marks created, which results in a poor alignment of the liquid crystal molecules by the corresponding alignment layer, and in turn a light-leaking effect in this region.

More specifically, FIG. 2 is a view of the cross section of the post spacer in FIG. 1 in the AA direction, wherein only one post spacer 110 is shown. In this figure the direction indicated by the one-way arrow is the rubbing direction in which the rubbing piles rub the organic resin layer on the post spacer 110, and the regions around the post spacer 110 are display region A and B. As stated above, the organic resin layer 120 corresponding to region A and region D is rubbed normally, while the organic resin layer 120 corresponding to region C is not rubbed or rubbed with shallow rubbing marks created. As a result, the liquid crystal molecules are insufficiently aligned by the alignment layer in region C, leading to a poor display of pictures in the dark state and even a presence of light spots (i.e. the light-leaking effect) in the display region around the post spacer, by which the quality of pictures of the final product is affected.

To summarize, there is a need for an improved arrangement of post spacers.

### SUMMARY OF THE DISCLOSURE

It would be advantageous to achieve a post spacer capable of improving the rubbing condition for the region around the post spacer on a display substrate. It would also be desirable to provide a display substrate with such post spacers to alleviate the bad effect in the pixel display region like light-leaking, etc.

To better address one or more of these concerns, according to a first aspect of the disclosure a post spacer is provided, a cross section of the post spacer in the direction perpendicular to the height direction comprising a first portion that is symmetrical with respect to an axis in a first direction, the maximal width of the first portion in a second direction perpendicular to the first direction being the maximal width of the whole cross section in the second direction, and the width of the first portion decreasing progressively along the first direction, wherein a shape between a vertex of the first portion in the first direction and each of the two endpoints defining said maximal width is a straight line, and an included angle between both straight lines is less than or equal to 90 degree, or a shape between a vertex of the first portion in the first direction and each of the two endpoints defining said maximal width is a convex arc, an included angle between both straight lines connecting respectively the vertex to each of the two endpoints is less than or equal to 90 degree, and the convex arc is different from a circular arc on the circle with the straight line segment connecting the two endpoints being the diameter thereof.

Optionally, the cross section further comprises a second portion having a side in common with the first portion, and the width of the second portion in the second direction increases progressively along the first direction. The second portion may conduct the rubbing piles that move with respect to the post spacer in such a manner that they sweep over the post spacer more smoothly, thus improving the rubbing condition further.

Optionally, the second portion and the first portion are center symmetrical to each other. In addition to facilitating the elimination of the skips produced when the rubbing piles sweep over the post spacers, center symmetrical parts are more easily manufactured and may provide a more uniformly supporting effect.

Optionally, the cross section is a diamond and an extending direction of the longer diagonal of the diamond is the first direction.

Optionally, the cross section is an ellipse and an extending direction of the major axis of the ellipse is the first direction.

According to a second aspect of the present disclosure, provided is a display substrate comprising a substrate body and a plurality of post spacers according to the first aspect formed on the substrate body.

Optionally, the display substrate further comprises an alignment layer covering the substrate body and the plurality of post spacers, the alignment direction of the alignment layer being the first direction.

Optionally, the display substrate is either a color filter substrate or an array substrate.

According to a third aspect of the present disclosure, provided is a method of manufacturing a display substrate comprising: forming a plurality of post spacers according to claim 1 on a substrate body, wherein the pattern of a mask is arranged to be the same as the cross section of the post spacer.

Optionally, the method further comprises: forming an alignment layer, on is the substrate body with the plurality of post spacers formed thereon, wherein the alignment direction of the alignment layer is the first direction.

The present disclosure can avoid the phenomenon that the regions around a post spacer on the display substrate are rubbed with shallow rubbing marks produced or simply not rubbed in forming the alignment layer, and thus alleviate the bad effect in the pixel display region around the post spacer like light-leaking, etc, by providing a post spacer with a cross section of a particular shape.

These and other aspects of the disclosure will be apparent from and elucidated with reference to the drawings and embodiment(s) described hereinafter.

### BRIEF DESCRIPTION OF DRAWINGS

FIG. 1 is a top view of a post spacer in the prior art;

FIG. 2 is a schematic view of the cross section of the post spacer in FIG. 1 in the AA direction;

FIG. 3 is a schematic view of a magnified post spacer according to an embodiment of the present disclosure;

FIG. 4 is a top view of the cross section of the post spacer shown in FIG. 3 in the direction perpendicular to the height direction;

FIG. 5 is a top view of the cross section of a post spacer according to another embodiment of the present disclosure in the direction perpendicular to the height direction;

FIG. 6 is a schematic view of a magnified post spacer according to another embodiment of the present disclosure;

FIG. 7 is a top view of the cross section of the post spacer shown in FIG. 6 in the direction perpendicular to the height direction;

FIG. 8 is a top view of the cross section of a post spacer according to another embodiment of the present disclosure in the direction perpendicular to the height direction;

FIG. 9 is a top view of the cross section of a post spacer according to another embodiment of the present disclosure in the direction perpendicular to the height direction; and

FIG. 10 is a top view of an array substrate according to an embodiment of the present disclosure.

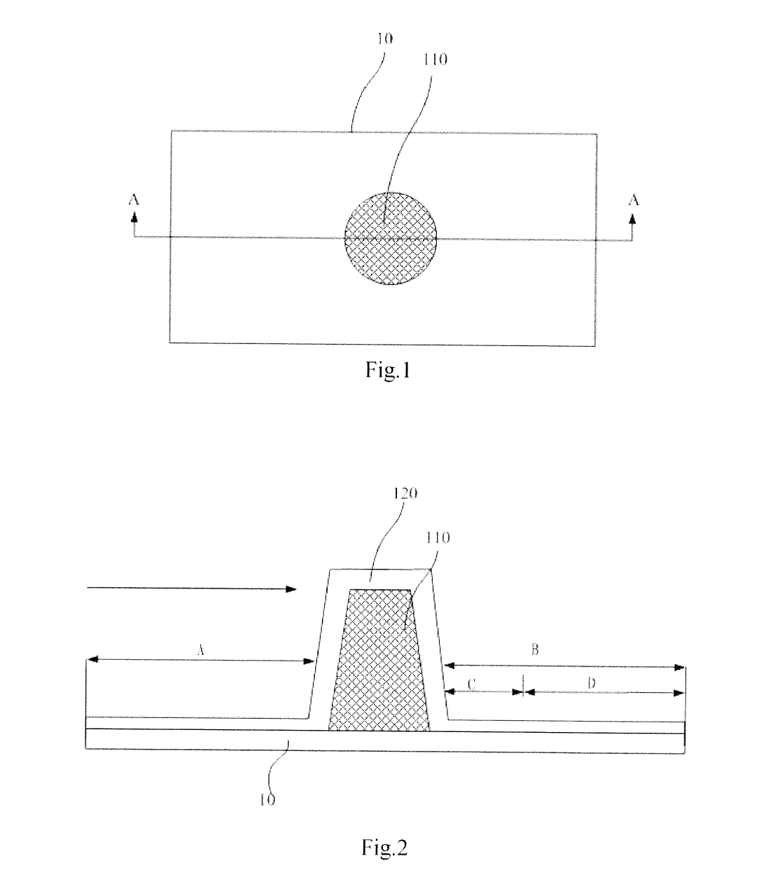

### DETAILED DESCRIPTION OF PREFERRED EMBODIMENTS

Various embodiments of the present disclosure will be explained hereinafter in detail with reference to the accompany drawings.

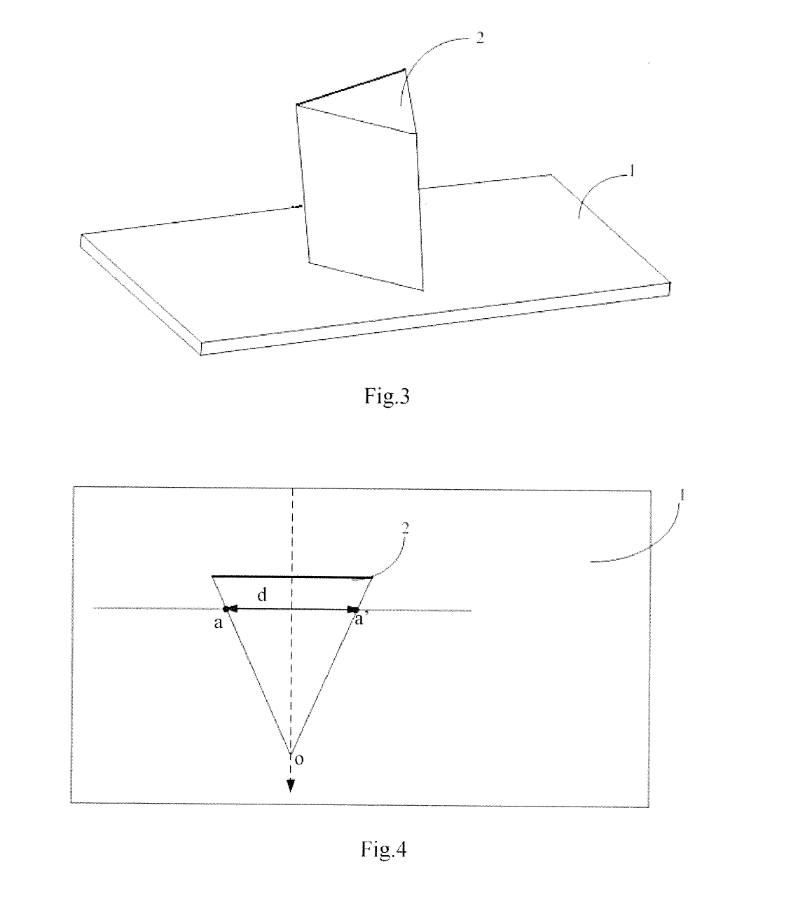

FIG. 3 is a schematic view of a magnified post spacer according to an embodiment of the present disclosure. For simplicity, only one post spacer 2 is arranged on the substrate body 1 in this example.

FIG. 4 is a top view of the cross section (i.e. the cross section in the plane being perpendicular to the height direction of the post spacer) of the post spacer shown in FIG. 3 in the direction perpendicular to the height direction, from which the spirit of the present disclosure may be better recognized. That is, in forming the alignment layer, in order to enable the rubbing piles (not shown) to fully contact the organic resin layer around the front end (e.g. the vertex o) of the post spacer 2 when sweeping over the post spacer 2 along the first direction indicated by the dashed arrow. It is necessary to form the post spacer 2 in such a manner that the contraction characteristic of its cross section from the two endpoints defining the maximal width to the vertex o along the first direction is superior to that of the circle in the prior art.

In the example shown in FIG. 4, the cross section of the post spacer 2 is an isosceles triangle which is symmetrical with respect to an axis in the first direction, the length of the base of the isosceles triangle (i.e. the maximal width in a second direction perpendicular to the first direction) being the maximal width of the whole cross section in the second direction. Obviously, the width of the cross section (i.e. the distance d between point a and point a′ in the figure) decreases progressively along the first direction. It is to be noted that not all isosceles triangles are applicable here. For example, in case the vertex angle of an isosceles triangle is an obtuse angle, or even an angle approximating 180 degree in extreme cases, such a post spacer would be a great obstacle in the direction of the movement of rubbing piles, preventing the rubbing piles from contacting the region around the front end (the vertex o) of the post spacer at all, not to mention improving the rubbing condition. In view of this, in this embodiment, the included angle between both straight lines connecting respectively the vertex o to each of the two endpoints of the base of the isosceles triangle may be less than or equal to 90 degree. This could be a tradeoff between a faster contraction speed and a weaker blockage.

In practical operation, the substrate body 1 with post spacers 2 and organic resin layer formed thereon moves with respect to the fixed rubbing piles in an opposite direction to the first direction, and thus the rubbing piles move with respect to the substrate body in the first direction. Therefore, from the top view, the rubbing piles sweep over the base of the isosceles triangle at first and then the front end (the vertex o) portion along the first direction. Due to a faster contraction speed of an isosceles triangle from the base to the vertex than that of a circle, the rubbing piles suffer a relatively weak resistance from the post spacer 2, and then continue to move toward the nearest organic resin layer upon they left the front end portion of the post spacer 2. This would not form an empty region where there is no rubbing mark in the alignment layer, but rather create an organic layer with deep rubbing marks present around the post spacer. Consequently, the rubbing marks around the front end portion of the post spacer share the same direction and depth with those in the region away from the post spacer 2. In this way, the problem of misorientation or failure to be initially orientated of the liquid crystal molecules due to a disordered arrangement or a shallow depth of rubbing marks may be avoided, when the post spacer 2 is formed on the substrate body 1.

In the above description, as an isosceles triangle, the cross section of the post spacer 2 is shown as rigidly symmetrical with respect to an axis in the first direction; however, this is illustrative and not limitive. The cross section may also be substantially symmetrical. In other words, there may be an included angle within a certain range (e.g. 0 to 7 degree) between the straight line connecting the vertex o to the midpoint of the base and the perpendicular bisector of the base.

Moreover, in addition to triangle, cross sections of other shapes are also applicable, as long as the contraction characteristics thereof from the two endpoints defining the maximal width in the second direction to the vertex are superior to that of the circle in the prior art.

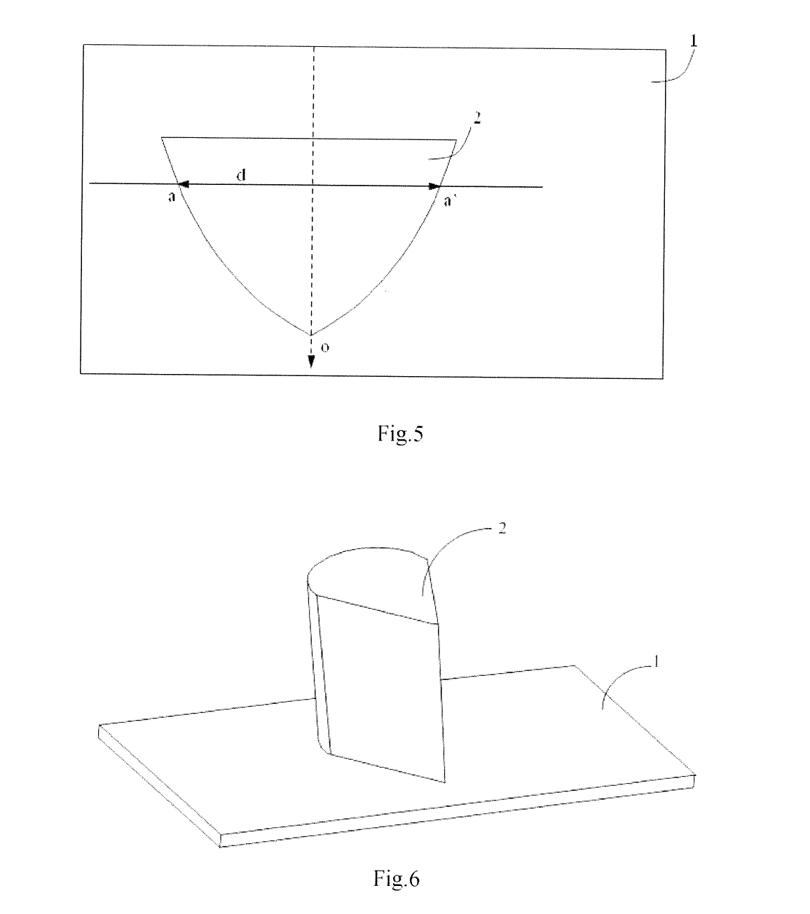

FIG. 5 is a top view of the cross section of a post spacer according to another embodiment of the present disclosure in the direction perpendicular to the height direction. As is shown in this figure, the shape between the vertex o and each of the two endpoints of the base (i.e. the maximal width of the cross section in the second direction) is a convex arc. Similarly, in this embodiment, the included angle between both straight lines connecting respectively each of the two endpoints to the vertex o may be less than or equal to 90 degree. In the case of 90 degree, the convex arc differentiates from the circular arc on a circle with the base being the diameter thereof in that the contraction speed from the two endpoints to the vertex is faster than the circular arc.

Further, in the above description, the cross section of the post spacer 2 is shown as rigidly symmetrical with respect to an axis in the first direction; however, this is illustrative and not limitive. The cross section may also be substantially symmetrical. In other words, there may be an included angle within a certain range (e.g. 0 to 7 degree) between the straight line connecting the vertex o to the midpoint of the base and the perpendicular bisector of the base.

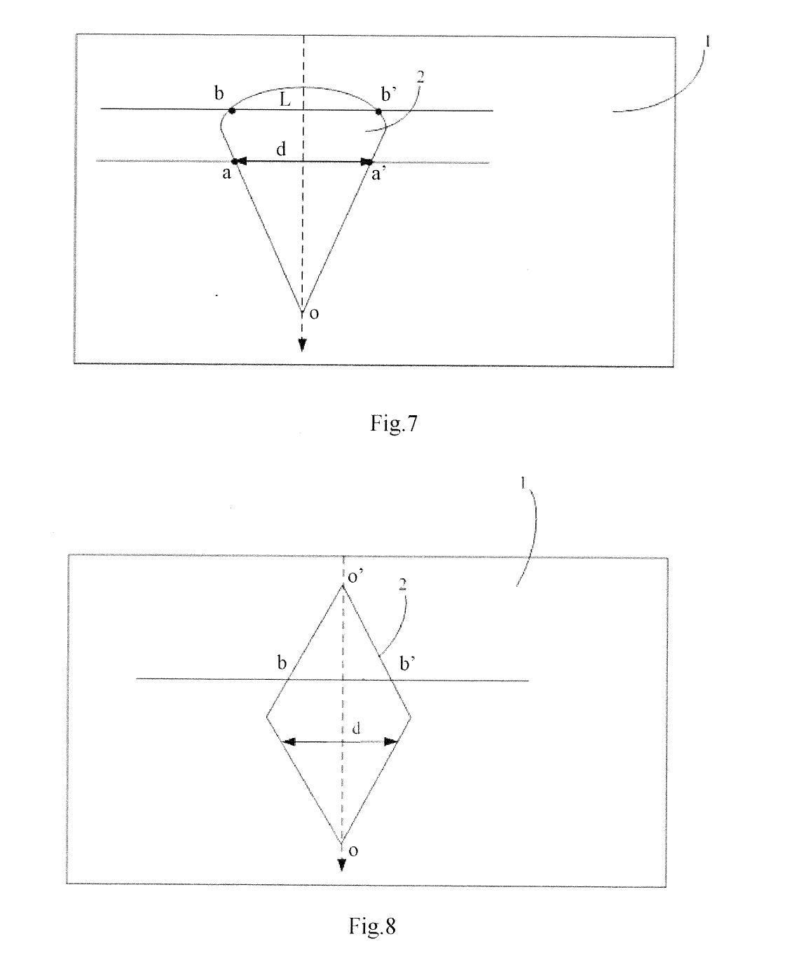

FIG. 6 is a schematic view of a magnified post spacer according to another embodiment of the present disclosure. The post spacer 2 has a relatively smooth structure at the side over which the rubbing piles sweep first in forming the alignment layer, as compared with the above embodiments. This helps to conduct the rubbing piles to sweep over the post spacer 2 more smoothly, which further improves the rubbing condition.

FIG. 7 is a top view of the cross section of the post spacer shown in FIG. 6 in the direction perpendicular to the height direction. As is shown in this figure, in addition to the first portion as the triangle with the vertex o, the cross section further comprises a second portion having a side in common with the first portion, wherein the width of the second portion in the second direction (i.e. the distance L between point b and point b′ in the figure) increases progressively along the first direction. In this specific example, the whole cross section is approximately a sector. Expressly, such a structure could reduce the resistance to the rubbing piles from the post spacer.

However, the structure shown in FIG. 7 is only illustrative, and the second portion of the cross section may also be of other shapes, as long as the width thereof in the second direction increases progressively along the first direction.

FIG. 8 is a top view of the cross section of a post spacer according to another embodiment of the present disclosure in the direction perpendicular to the height direction. The cross section comprises a bottom triangle (or a first portion) with the vertex o and a top triangle (or a second portion) with the vertex o′, wherein the bottom triangle is the same as the one in FIG. 4 and the top triangle meets the requirement that the width in the second direction increase progressively along the first direction. In particular, in this example, the first portion and the second portion of the cross section are shown as center symmetrical to each other, i.e. the cross section is a diamond, the extending direction of the longer diagonal of which is the first direction.

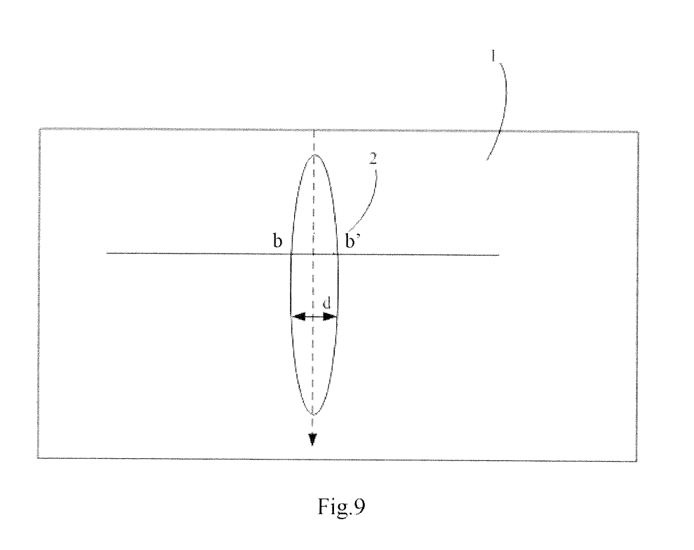

FIG. 9 is a top view of the cross section of a post spacer according to another embodiment of the present disclosure in the direction perpendicular to the height direction. In this embodiment, as another example in which the first portion and the second portion are center symmetrical to each other, the cross section is an ellipse, the extending direction of the major axis of which is the first direction. It can be seen that the cross section of the post spacer 2 is shorter in the second direction and longer in the first direction (i.e. the rubbing direction), which facilitates the reduction of the resistance to the rubbing piles.

The post spacers provided by above embodiments each having an elaborated cross section, the resistance suffered become weaker and weaker when the rubbing piles of the rubbing cloth sweep over the front end portion of the post spacers, reducing the risk that there will be a region in which rubbing skips are present on the organic resin layer where the alignment layer is to be formed.

It should be understood that the cross section of a post spacer is generally limited to the size of black matrices (BM) and the supporting capability required when the post spacer is applied to a display substrate (e.g. a color filter substrate or an array substrate). Specifically, since the post spacer is generally produced above a black matrix, whose width is, for example, 22 to 32 microns in the state of the art, the length of the cross section of the post spacer in the first direction, in general, should fall into this range. Additionally, in order to ensure the supporting capability of the post spacer, the area of the cross section should not be less than a certain value, and thus the width in the second direction should not be too small. Taking the triangle shown in FIG. 4 as an example, the base is generally larger than 8 microns in length.

A display substrate is further provided by the present disclosure, which comprises a substrate body and a plurality of post spacers formed on the substrate body, wherein the post spacers may be those provided by each of the above-mentioned embodiments. Additionally, the display substrate may further comprise an alignment layer covering the substrate body and the plurality of post spacers, the alignment direction of which being the first direction. The display substrate may be either a color filter substrate or an array substrate. Further, an alignment layer may be formed on the substrate body with the plurality of post spacers formed thereon, wherein the alignment direction of the alignment layer is the first direction.

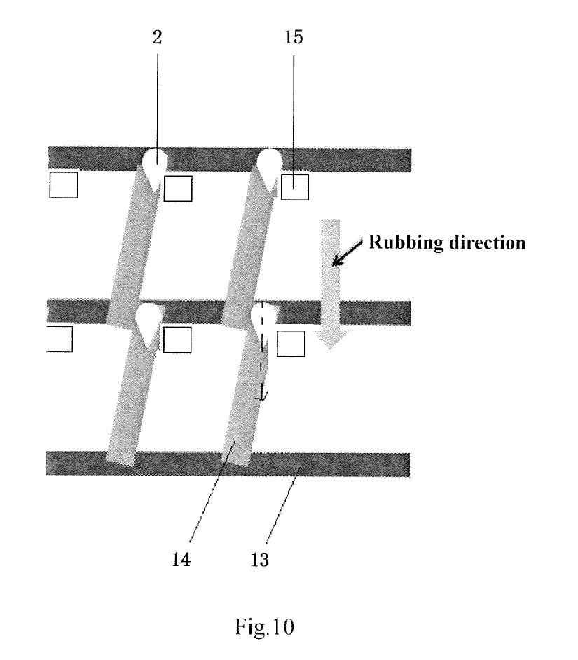

As an example, FIG. 10 shows a top view of an array substrate according to an embodiment of the present disclosure. There are post spacers 2, mutually crosswise arranged gate lines 13 and data lines 14, as well as thin film transistors (TFT) 15 formed on the array substrate, wherein the alignment direction of the alignment layer is the first direction (i.e. the direction indicated by the dashed arrow in the figure).

In the procedure of aligning, there may be two modes as follows:

Mode 1: the included angle between a certain side of the pixel and an edge of the substrate is 3 to 8 degree, the included angle between the rubbing direction and an edge of the substrate is 0 degree, and the extending direction of the post spacers is the rubbing direction.

Mode 2: the included angle between a certain side of the pixel and an edge of the substrate is 0 degree, the included angle between the rubbing direction and an edge of the substrate is 3 to 8 degree, and the extending direction of the post spacers is the rubbing direction.

It is to be understood that a display substrate with post spacers according to the present disclosure formed thereon can be manufactured using a procedure compatible with the existing manufacturing method of display substrates, wherein there is only a need for the pattern of the mask to be arranged to be the same as the cross section of the post spacer, without any other process needed. In the following the procedure of forming a color filter substrate is taken as an example for illustration.

Firstly, a black matrix layer of approximately 1.5 microns in thickness is prepared using a coating process on a glass substrate. The black matrix may be made of light-blocking polymer resin, and a black matrix pattern is formed on the glass substrate using a mask through exposure and development.

Then, a red pixel resin layer of approximately 2.5 microns in thickness is coated on the color filter substrate using a coating dispersion method. The pixel resin is generally acrylic photosensitive resin or other carboxylic acid-type pigment resins. Patterns of red pixels are then formed in a certain region of the glass substrate by exposure and development. After this, patterns of blue and green pixels resin layer (about 2.5 microns in thickness) are prepared on the color filter substrate using the same process in preparing the red pixels.

Next, a resin layer is coated on the glass substrate and then post spacers are formed by exposure and photolithography. The cross section of the post spacers may be of the shapes provided by various embodiments mentioned above.

In summary, these structures describe above are able to alleviate effectively the blockage of the post spacer to the rubbing piles in forming the alignment layer, increasing the quality of rubbing on the pixel display region of the display substrate, and in turn the quality of display of the pictures.

While the disclosure has been illustrated and described in detail in the drawings and foregoing description, such illustration and description are to be considered illustrative or exemplary and not restrictive; the disclosure is not limited to the disclosed embodiments.

Additionally, variations to the disclosed embodiments can be understood and effected by the skilled person in practicing the claimed subject matter, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage.

1. A post spacer, a cross section of the post spacer in the direction perpendicular to the height direction comprising a first portion that is symmetrical with respect to an axis in a first direction, the maximal width of the first portion in a second direction perpendicular to the first direction being the maximal width of the whole cross section in the second direction, and the width of the first portion decreasing progressively along the first direction,
wherein a shape between a vertex of the first portion in the first direction and each of the two endpoints defining said maximal width is a straight line, and an included angle between both straight lines is less than or equal to 90 degree,
or
a shape between a vertex of the first portion in the first direction and each of the two endpoints defining said maximal width is a convex arc, an included angle between both straight lines connecting respectively the vertex to each of the two endpoints is less than or equal to 90 degree, and the convex arc is different from a circular arc on the circle with the straight line segment connecting the two endpoints being the diameter thereof.

2. The post spacer according to claim 1, wherein the cross section further comprises a second portion having a side in common with the first portion, and the width of the second portion in the second direction increases progressively along the first direction.

3. The post spacer according to claim 2, wherein the second portion and the first portion are center symmetrical to each other.

4. The post spacer according to claim 3, wherein the cross section is a diamond and an extending direction of the longer diagonal of the diamond is the first direction.

5. The post spacer according to claim 3, wherein the cross section is an ellipse and an extending direction of the major axis of the ellipse is the first direction.

6. A display substrate comprising a substrate body and a plurality of post spacers according to claim 1 formed on the substrate body.

7. The display substrate according to claim 6, wherein the display substrate further comprises an alignment layer covering the substrate body and the plurality of post spacers, the alignment direction of the alignment layer being the first direction.

8. The display substrate according to claim 6, wherein the display substrate is either a color filter substrate or an array substrate.

9. A method of manufacturing a display substrate comprising:
forming a plurality of post spacers according to claim 1 on a substrate body, wherein the pattern of a mask is arranged to be the same as the cross section of the post spacer.

10. The method according to claim 9 further comprises:
forming an alignment layer, on the substrate body with the plurality of post spacers formed thereon, wherein the alignment direction of the alignment layer is the first direction.
